(19) United States
(12) Patent Application Publication
(10) Pub. No.: US 2025/0353733 A1
(43) Pub. Date: Nov. 20, 2025

(54) ELECTROACOUSTIC TRANSDUCER, ARRAY SPEAKER, WEARABLE DEVICE, SPEAKER, ULTRASONIC TRANSMITTER, AND METHOD OF MANUFACTURING ELECTROACOUSTIC TRANSDUCER

(71) Applicants: Shuichi SUZUKI, Tokyo (JP); Wataru YOKOTA, Tokyo (JP)

(72) Inventors: Shuichi SUZUKI, Tokyo (JP); Wataru YOKOTA, Tokyo (JP)

(21) Appl. No.: 19/196,835

(22) Filed: May 2, 2025

(30) Foreign Application Priority Data
May 16, 2024 (JP) 2024-080314
Jan. 17, 2025 (JP) 2025-006674

(51) Int. Cl. B81B 3/00; B81C 1/00; H04R 1/02; H04R 1/40; H04R 17/00

(52) U.S. Cl. CPC B81B 3/0054; B81C 1/00158; H04R 1/025; H04R 1/403; H04R 17/00; B81B 2201/0257; B81B 2203/0127; H04R 2201/003; H04R 2400/11; H04R 2499/11

(57) ABSTRACT

An electroacoustic transducer includes a diaphragm, a diaphragm support connected to a part of the diaphragm in a direction of vibration of the diaphragm, a driver connected to the diaphragm support to vibrate the diaphragm, a driver support connected to the driver opposite to the diaphragm to support a part of the driver, a base connected to the driver support and having a larger area than the diaphragm, and a frame connected to the base from a same side as the driver support and disposed within a gap between an outside of the diaphragm and an outside of the driver.

### CROSS-REFERENCE TO RELATED APPLICATIONS

This patent application is based on and claims priority pursuant to 35 U.S.C. § 119(a) to Japanese Patent Application No. 2024-080314, filed on May 16, 2024, and Japanese Patent Application No. 2025-006674, filed Jan. 17, 2025, in the Japan Patent Office, the entire disclosure of each are hereby incorporated by reference herein.

### BACKGROUND

### Technical Field

The present disclosure relates to an electroacoustic transducer, an array speaker, a wearable device, a speaker, an ultrasonic transmitter, and method of manufacturing electronic transducer.

### Related Art

Currently, acoustic devices such as earphones have been developed for use in, for example, listening to music, watching moving images, or joining video conferences. The acoustic device includes a speaker driver as an electroacoustic transducer produced by, for example, a microelectromechanical systems (MEMS) technology. In particular, In recent years, piezoelectric-driven MEMS speaker drivers using piezoelectric membranes have become popular for miniaturization.

### SUMMARY

According to an embodiment of the present disclosure, an electroacoustic transducer includes a diaphragm, a diaphragm support connected to a part of the diaphragm in the direction of vibration of the diaphragm, a driver connected to the diaphragm support and vibrating the diaphragm, a driver support connected to the driver opposite to the diaphragm and supporting a part of the drive part, a base connected to the driver support and having a larger area than the diaphragm, and an frame connected to the base from the same side as the driver support and disposed with a gap between the outside of the diaphragm and the outside of the driver.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a cross-sectional view of one embodiment example of an electroacoustic transducer;

FIG. 2 is a plan view of the electroacoustic transducer illustrated in FIG. 1, in which the illustration of a diaphragm and a base are omitted;

FIG. 3A is a cross-sectional view of portion of an electroacoustic transducer illustrated in FIG. 1;

FIG. 3B is a plan view of portion of an electroacoustic transducer illustrated in FIG. 1;

FIG. 3C is a cross-sectional view of portion of an electroacoustic transducer illustrated in FIG. 1;

FIG. 3D is a plan view of portion of an electroacoustic transducer illustrated in FIG. 1;

FIG. 3E is a cross-sectional view of portion of an electroacoustic transducer illustrated in FIG. 1;

FIG. 3F is a plan view of portion of an electroacoustic transducer illustrated in FIG. 1;

FIG. 4A is a plan view of a beam of a further embodiment example of the electroacoustic transducer;

FIG. 4B is a plan view of a beam of a further embodiment example of the electroacoustic transducer;

FIG. 5 is a graph of a result of a simulation of the relationship between a gap and a sound pressure level;

FIG. 6 is a cross-sectional view of a further embodiment example of the electroacoustic transducer;

FIG. 7 is a cross-sectional view of a further embodiment example of the electroacoustic transducer;

FIG. 8 is a plan view of a diaphragm and a frame of a further embodiment example of the electroacoustic transducer;

FIG. 9 is a perspective view of a further embodiment example of the electroacoustic transducer, in which the illustration of a diaphragm and a base are omitted;

FIG. 10 is a plan view of a diaphragm and a frame of a further embodiment example of the electroacoustic transducer;

FIG. 11 is a perspective view of a further embodiment example of the electroacoustic transducer, in which the illustration of a diaphragm and a base are omitted;

FIG. 12 is a cross-sectional view of a further embodiment example of the electroacoustic transducer;

FIG. 13 is a plan view of a further embodiment example of the electroacoustic transducer, in which the illustration of a diaphragm, a frame and a base are omitted;

FIG. 14 is a perspective view of the electroacoustic transducer illustrated in FIG. 13, in which the illustration of a diaphragm, a frame and a base are omitted;

FIG. 15A is a plan view of a diaphragm of a further embodiment example of the electroacoustic transducer;

FIG. 15B is a plan view of the electroacoustic transducer illustrated in FIG. 15A, in which the illustration of a diaphragm, a frame and a base are omitted;

FIG. 16A is a plan view of a diaphragm and a frame of a further embodiment example of the electroacoustic transducer;

FIG. 16B is a plan view of a diaphragm and a frame of the electroacoustic transducer illustrated in FIG. 16A;

FIG. 17 is a schematic view of an eyeglasses-type wearable device;

FIG. 18 is a schematic view of a watch-type wearable device;

FIG. 19 is a schematic view of an earphone speaker; and

FIG. 20 is a schematic view of an ultrasonic transmitter.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

The following is a description of the embodiments of the disclosure with reference to the drawings. In each drawing, the same reference signs are attached to the same configuration parts, and redundant description is appropriately simplified or omitted.

Further, the embodiments described below are some examples of an electroacoustic transducer, an array speaker, a wearable device, a speaker, or an ultrasonic transmitter, and method of manufacturing electronic transducer for embodying the technical idea of the present disclosure, and embodiments of the present disclosure are not limited to the embodiments described below.

Unless otherwise specified, shapes of components, relative arrangements thereof, and values of parameters described below are not intended to limit the scope of the present disclosure but are intended to exemplify the scope of the present disclosure. For example, the size and positional relation of components illustrated in the drawings may be exaggerated for clarity of description.

In each drawing, the mutually orthogonal X-axis, Y-axis, and Z-axis directions may be illustrated. The X-axis direction includes the direction indicated by the arrow and vice versa; the direction in the X-axis direction to which the arrow points may be described as the +X direction and the direction opposite to the +X direction as the −X direction. The Y-axis direction includes the direction indicated by the arrow and vice versa; the direction in the Y-axis direction to which the arrow points may be described as the +Y direction and the direction opposite to the +Y direction as the −Y direction. The Z-axis direction includes the direction indicated by the arrow and vice versa; the direction in the Z-axis direction to which the arrow points may be described as the +Z direction and the direction opposite to the +Z direction as the −Z direction.

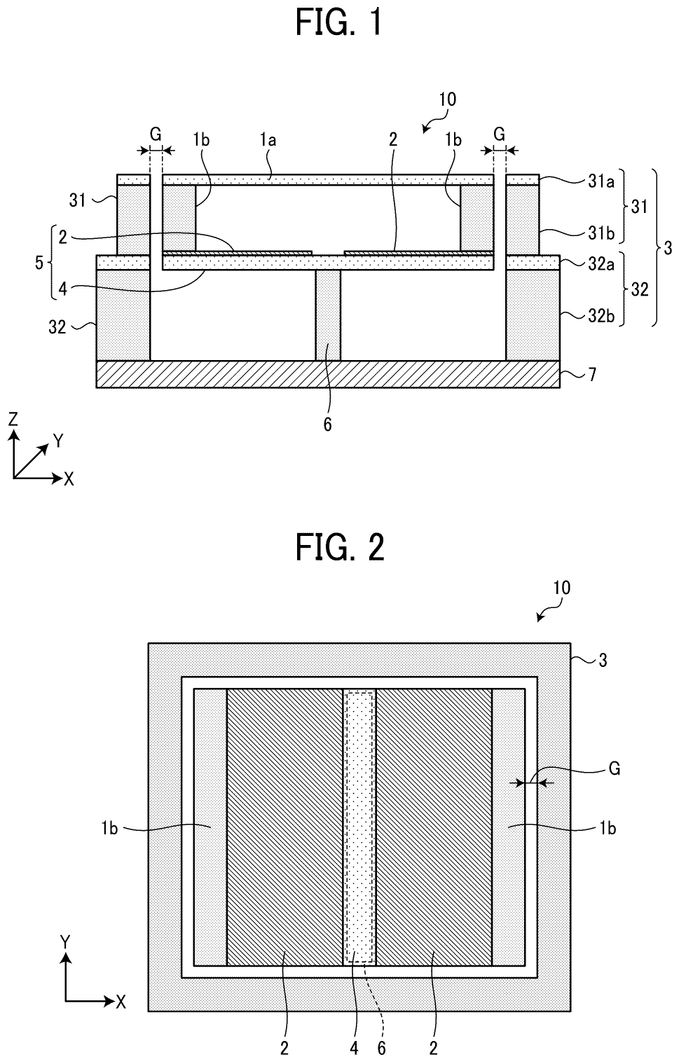

FIG. 1 is a cross-sectional view of one embodiment example of an electroacoustic transducer. FIG. 2 is a plan view of the electroacoustic transducer illustrated in FIG. 1, in which the illustration of a diaphragm and a base are omitted. As illustrated in FIG. 1, an electroacoustic transducer 10 includes a diaphragm 1a, diaphragm supports 1b, a frame 3, a driver 5, a driver support 6, and a base 7. The diaphragm 1a generates sound waves by vibration. The diaphragm supports 1b supports the diaphragm 1a. As illustrated in FIG. 1, two diaphragm supports 1b are arranged in the vibration direction (Z direction in FIG. 1) of the diaphragm 1a.

The driver 5 includes driving sources 2 and a driving plate 4. The driving plate 4 supports the diaphragm 1a and drive sources 2 that are stacked on the driving plate 4. One end of the driver support 6 supports the driver 5 and the other hand of the driver supporter 6 connects to the base 7.

The base 7 supports the driver support 6 and the frame 3. The frame 3 and the driver supporter 6 extend in the same direction from one side of the base 7.

The frame 3 includes a first frame 31 and a second frame 32. The first frame 31 surrounds the outside of the diaphragm 1a. The second frame 32 surrounds the outside of the driver 5.

In the electroacoustic transducer 10, the driver 5 is fixed to the driver support 6 to support the driver 5, and the driver 5 vibrates around the driver supporter 6 as a fixed end in the Z direction (direction in which the diaphragm 1a and the driver 5 are opposed to each other, i.e., a vibration direction, in other words, an opposing direction) by an electrical signal input to the driving sources 2. The electroacoustic transducer 10 is a device that generates vibration such as sound by the diaphragm 1a that vibrates in the Z direction in accordance with the vibration of the driver 5. Each part of the electroacoustic transducer 10 will be described below in detail.

The driver support 6 is a support member having a longitudinal direction in the Y direction. The driver support 6 is disposed at a region indicated by an alternate long and short dash line in FIG. 2, on the side of the driving plate 4 opposite the driving sources 2 as illustrated in FIG. 1. The driver support 6 illustrated in FIG. 2, is disposed so that the driver supporter 6 passes through the center of the driver 5 in the X direction and extends in the direction of extension of the diaphragm supports 1b (Y direction). This arrangement allows the diaphragm 1a to vibrate parallel to the Z direction, as the distance of the driver 5 from the driver support 6 in the X direction is constant and the connection positions of the driver 5 and the diaphragm support 1b vibrate with the same displacement.

The driver support 6 may be larger than the region indicated by the alternate long and short dash line in FIG. 2. For example, a part of the region where the driver support 6 is disposed may overlap the driver 5. Further, for example, the end of the driver support 6 in the Y direction may project from the driving plate 4.

The driving sources 2 may be arranged on either the upper or lower face of the driving plate 4 in the Z direction. The driving sources 2 may be arranged on both sides of the driving plate 4.

The driver support 6 has a single-layer structure or a multiple-layer structure formed of, for example, an inorganic material or an organic material. The driver support 6 is preferably formed of single crystal silicon of a silicon on insulator (SOI) substrate. When the driver support 6 is formed of multiple layers, an interlayer film formed of, for example, silicon oxide may be disposed between the layers of the driver support 6 or between the driving plate 4 and the driver support 6.

The driving plate 4 is laminated on the driver support 6 in the +Z direction, and extends in the +X direction or the −X direction from the driver support 6 disposed at the center of the driving plate 4 (multiple driving sources 2). The driving plate 4 is formed of, for example, an oxide material, an inorganic material, or an organic material. The driving plate 4 is preferably formed of a silicon active layer. A region of the driving plate 4 extending from the driver support 6 in the X direction is supported by the driver support 6, and is elastically deformable around the fixed end in the Z direction like a so-called cantilever structure. A portion of the driving plate 4 laminated on the driver support 6 is the fixed end. The diaphragm supports 1b and the driving sources 2 are disposed on the side of the driving plate 4 opposite the driver support 6.

The diaphragm supports 1b are opposed to the driver 5 and the diaphragm 1a in the Z direction, and couples the driver 5 and the diaphragm 1a. The diaphragm supports 1b have a longitudinal direction which is the same direction as the longitudinal direction of the driver support 6, and is formed along the side of the driving plate 4 at the end in the X direction (extending direction of the driving plate 4 and the diaphragm 1a). The diaphragm supports 1b illustrated in FIGS. 1 and 2 are arranged lineally symmetrically with a line parallel to the Y axis passing through the center of the diaphragm 1a in the plane of the diaphragm 1a. The diaphragm supports 1b may be arranged in the plane of the diaphragm 1a facing in the vibration direction, line symmetrically with respect to a line passing through the center of gravity of the diaphragm 1a. This arrangement allows the diaphragm 1a to be driven in translation.

The diaphragm supports 1b illustrated in FIGS. 1 and 2 are laminated on the driving sources 2 respectively, but may be laminated on the driving plate 4. The diaphragm supports 1b are not necessarily formed along the side of the driving plate 4 at the end in the X direction. For example, the diaphragm supports 1b may be formed on the inner side in the X direction (the center side of the driving plate 4) with respect to the end of the driving plate 4.

The distance between the connection position of the diaphragm supports 1b and the driver 5 and the center of gravity of the driver 5 is longer than the distance between the connection position of the driver support 6 and the driver 5 and the center of gravity of the driver 5. In other words, in the plan view as illustrated in FIG. 2, the driver support 6 is disposed closer to center in the plane of the driver 5 than the diaphragm supports 1b. this disposal allows to increase the displacement of the driver 5 and increase the sound pressure level.

The connection position between the driver support 6 and the driver 5 do not overlap the connection position between the diaphragm supports 1b and the driver 5 on the opposite side of the face where the driver 5 connects to the drive supports 1b. In other words, the diaphragm supports 1b and the driver 5 do not overlap in the direction perpendicular to the plane (Z direction) as viewed from the face of the driver 5.

The driving sources 2 are a piezoelectric actuator (piezoelectric film) that is driven by a voltage applied thereto. The driving sources 2 are electrically connected to an external control device that controls a signal for generating vibration such as sound and transmits the signal to the electroacoustic transducer 10. The driving sources 2 each includes a lower electrode, a piezoelectric body, and an upper electrode laminated in this order on the driving plate 4. The lower electrode and the upper electrode are formed of, for example, gold (Au) or platinum (Pt). The piezoelectric body is formed of, for example, lead zirconate titanate (PZT) which is a piezoelectric material. However, the material forming the piezoelectric body is not limited thereto. The driving sources 2 may include multiple layers of the piezoelectric bodies and an intermediate electrode therebetween.

When a voltage is applied to the driving sources 2 respectively, a strain is generated in the in-plane direction (XY direction) in the piezoelectric body of the driving sources 2, and the driving plate 4 is deformed in the Z direction. As the voltage applied to the driving sources 2 change with time, the surface of the diaphragm 1a vibrates via the diaphragm supports 1b to generate a pressure wave in ambient air, which is sensed by a person as a sound. An input voltage waveform is electrically converted from a waveform of a sound to be reproduced. This voltage waveform is input to the driving sources 2 to reproduce the sound.

A plurality of driving sources 2 are formed in linear or point symmetry across the area where the driving plate 4 and driver supporter 6 are stacked. The arrangement of the driving sources 2 having symmetry can reduce deformation of the diaphragm 1 during vibration.

The diaphragm 1a is a rectangular plate. The diaphragm 1a is joined to the driver 5 via the diaphragm supports 1b in the Z direction on two sides opposed to each other in the X direction. In other words, the diaphragm 1a is opposed to the driver 5 and the diaphragm supports 1b in the Z direction. The area of the diaphragm 1a as viewed in the Z direction (in plan view) is preferably equal to or larger than the total area of the driving plate 4 and the diaphragm supports 1b in plan view. The shape of the diaphragm 1a is not limited to a rectangle, and may be any desired shape.

The frame 3 is connected to the base 7 and is disposed around the outer frame of the diaphragm 1a and the driver 5. The frame 3 is not fixed to the outer frame of the driver 5, but is disposed at a predetermined distance from the outer frame of the diaphragm 1a and the outer frame of the driver 5. The arrangement of the frame 3 surrounding the diaphragm 1a and the driver 5 can increase the movable range of the driver 5 and increase the sound pressure level per unit area of diaphragm 1a. The arrangement of the frame 3 having a predetermined distance from the diaphragm 1a can controls the sound waves generated on the face of the diaphragm 1a facing the driver 5 from going around to the opposite side of the diaphragm 1a. Also, the arrangement of the frame 3 having a predetermined distance from the diaphragm 1a can increase the sound pressure level per unit area of the diaphragm 1a. In other words, the sound waves of the opposite phase generated on the back surface of the diaphragm 1a (the surface in the −Z direction) can be suppressed from going around to the surface (the surface in the −Z direction). The sound waves generated on the back surface of the diaphragm 1a are in opposite phase to those generated on the front surface of the diaphragm 1a.

The diaphragm 1a and the diaphragm supports 1b are formed, for example, by the MEMS (Micro Electro Mechanical Systems) process. The MEMS process is more productive and cost-effective than conventional methods, making it possible to provide electroacoustic transducers 10 with high-quality to a wider market.

For example, the diaphragm 1a is formed of silicon by a MEMS process. However, the process and material for forming the diaphragm 1a are not limited thereto. As the material for forming the diaphragm 1a, for example, a metal such as magnesium, titanium, or aluminum, carbon nanofibers, cellulose nanofibers, paper, or carbon fiber reinforced plastics (CFRP) can be selected.

The first frame 31 includes a first layer 31a and a second layer 31b. The second outer frame section 32 includes a third layer 32a and a fourth layer 32b.

The diaphragm 1a, the driving plate 4, the first layer 31a and the third layer 32a are formed similar substance which is, for example, oxidized materials, inorganic materials, organic materials, and preferably formed with silicon active layer.

The diaphragm supports 1b, the driver support 6, the second layer 31b and the fourth layer 32b are formed similar substance which is, for example, a single or multiple layers of inorganic or organic materials, preferably formed of single-crystal silicon on an SOI substrate. When the second layer 31b and the fourth layer 32b has multiple layers, an interlayer film composed of silicon oxide or an interlayer film formed of silicon oxide or the like may be included.

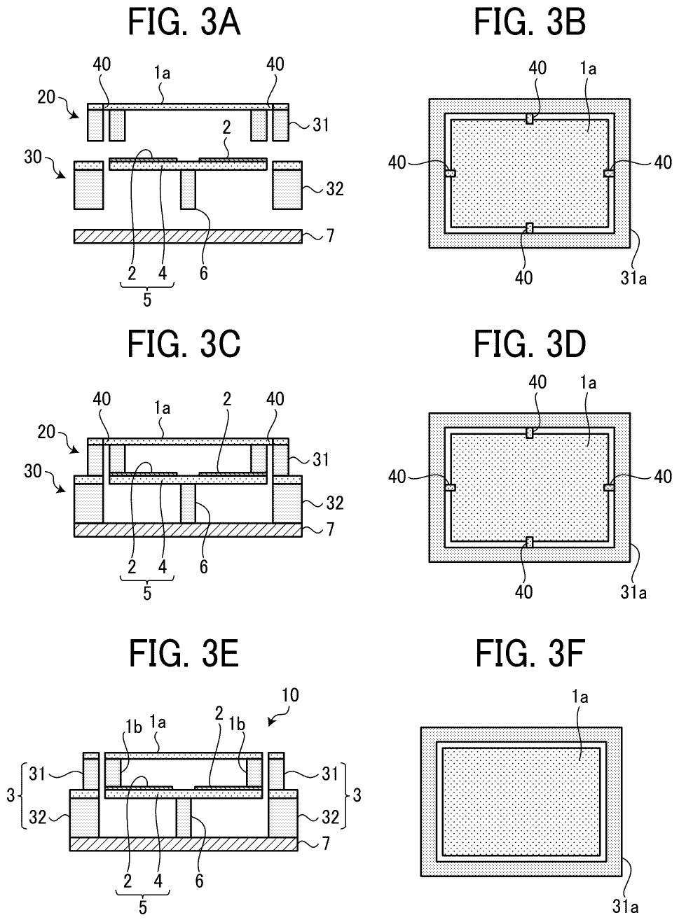

The manufacturing method of the electroacoustic transducer 10 by the MEMS process will be described below with FIGS. 3A-3F.

FIGS. 3A, 3C and 3E are a cross-sectional view of portion of an electroacoustic transducer illustrated in FIG. 1. FIGS. 3B, 3D and 3F are a plan view of portion of an electroacoustic transducer illustrated in FIG. 1. The manufacturing method of the electroacoustic transducer 10 illustrated in FIGS. 3A-3F is realized by the MEMS process.

First, the SOI wafer is formed by stacking the support layer (single crystal silicon of the SOI substrate) and silicon active layer. Next, the pattern formation is performed on the SOI wafer. The patterning can be provided by photolithography and etching, or by lift-off using resist patterns. Thereafter, a structure 20 and a structure 30 are formed from the etching from the front and back surfaces to form as illustrated in FIGS. 3A and 3B (a first and a second processes).

As illustrated in FIG. 3A, the structure 20 is a first member that includes the diaphragm 1a, the diaphragm supports 1b, the first frame 31, and a plurality of beams 40. The structure 30 is a second member that includes the driver 5, the driver support 6, and the second frame 32. As illustrated in FIG. 3A, the structure 20, the structure 30, and the base 7 are prepared separately.

As illustrated in FIG. 3A, a part of the diaphragm 1a is connected to the frame 3 (the first frame 31) via a plurality of the beams 40. The beam 40 has a structure that is broken when, for example, a voltage is applied to the driving sources 2 of the driver 5 to drive it. The width of the connection with the diaphragm 1a at the beam 40 is ⅓ or less of the length of one side of the diaphragm 1a on which the beam 40 is provided. The diaphragm 1a may be circular. When the diaphragm 1a is circular, the beam 40 is ⅓ or less of the width of the diameter of the circle of the diaphragm 1a. The width of the beam is ⅓ or less of the length of the circular diameter of the diaphragm 1a, which allows the beam 40 to break easier.

Next, the die bonding which the structure 20 (the diaphragm 1a which is connected to the frame 3 (the first frame 31), and the diaphragm supports 1b) connects to the structure 30 (the driver 5 and the second frame 32) with an adhesive such as silver paste is performed as illustrated in FIGS. 3C and 3D. The die bonding which the structure 20 connects to the base 7 with an adhesive such as silver paste is performed. In this embodiment example, the process of connecting the structure 20 and the structure 30 to the base 7 after bonding the structure 20 and the structure 30 is described, but the order of connecting is not limited to this.

Next, the beams 40 are broken or removed in a predetermined method as illustrated in FIGS. 3E and 3F. The predetermined method is, for example, applying voltage to the driving sources 2 of the driver 5 to break or remove the beams 40 (fourth process).

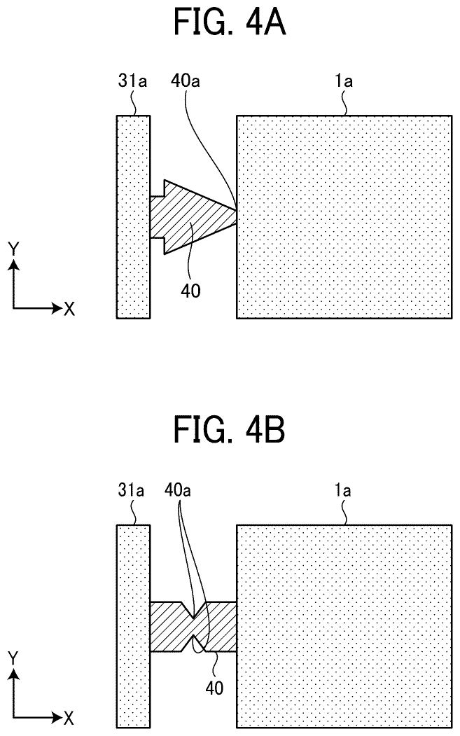

Here, the examples of the beams 40 will be described with FIGS. 4A and 4B. As illustrated FIGS. 4A and 4B, the beam 40 has a narrow width region 40a that locally reduces the area of the beam 40. The narrow width region 40a is disposed at a specific location of the beam 40, for example, in the middle of the beam 40. The example of the narrow width region 40a illustrated in FIG. 4A is shaped so that the connection position with the diaphragm 1a causes the stress concentration. The example of the narrow width region 40a illustrated in FIG. 4B is a notch on at least one side of the beam 40 in the width direction and is shaped so that the notch position causes the stress concentration. The narrow width 40a is the starting point of breaking the beam 40. The narrow width 40a can prevent unintentional fracture in other parts of the beam 40a.

The beam 40 with the narrow width 40a maintains the proper positioning of the diaphragm 1a and the frame 3 and improves the accuracy and quality of the diaphragm 1a and the frame 3 in the MEMS process.

The structure of the beam 40 with the narrow width 40a is particularly effective in the bonding the integrally formed the diaphragm 1a and the frame 3 with the driver 5. The beams 40 are broken or removed by applying voltage to the driving sources 2 of the driver 5 to break or remove the beams 40. Since the destruction is performed while the diaphragm 1a and the frame 3 are fixed in the proper position, the accuracy and reproducibility of the product are improved.

Generally, when a diaphragm is vibrated, sound waves in the opposite phase to those on the front side, which are generated on the back side of the diaphragm, are transmitted to the front side of the diaphragm, reducing the sound pressure level. In this embodiment example, the frame 3 prevents sound waves of the opposite phase generated on the back side of the diaphragm 1a from going around to the front side of the diaphragm 1a, thereby increasing the sound pressure level. The distance between the diaphragm 1a and the frame 3 should be less than 5 km.

In this embodiment example as illustrated in FIG. 1, the driver 5 and the driver support 6 are arranged in the same direction with respect to the face of the diaphragm 1a (−Z direction). The driver 5 (multiple driving sources 2) extend from the driver supporter 6 disposed at the center of the driver 5 (multiple driving sources 2). In other words, the driver 5 has a so-called cantilever structure having the fixed end at which the driver 5 is laminated on the driver supporter 6, to drive the diaphragm 1a. Such a configuration can obtain a large displacement as compared with the configuration in which both ends of the driver 5 are fixed, and thus the amplitude of the vibration of the diaphragm 1a can be increased. As a result, the sound pressure level per unit area of the diaphragm 1a can be enhanced.

The driver 5 drives both ends of the diaphragm 1a via the diaphragm supports 1b. Such a configuration reduces the distortion of the vibration surface of the diaphragm 1a due to the driving force as compared with the configuration in which the center of the diaphragm 1a is driven, and allows the vibration surface of the diaphragm 1a to vibrate in parallel to the Z direction (vibration direction). As a result, the distortion, i.e., total harmonic distortion (THD) that is generated when the electroacoustic transducer 10 is driven can be reduced.

In these embodiment examples as described above, the diaphragm 1a and the part of the frame 3 are connected by the thin, breakable beam 40. The beam 40 maintains a gap of 5 μm or less between the diaphragm 1a and a part of the frame 3, and they are bonded to the driver 5. After the diaphragm 1a, which is connected to the frame 3, is fixed to the driver 5 using an adhesive, a voltage is applied to the driving sources 2 of the driver 5 to operate the diaphragm 1a and break the beam 40. This method allows the production of an electroacoustic transducer of the present embodiment examples with a gap of 5 μm or less between the frame 3 and the diaphragm 1a using the MEMS process, allowing for efficient manufacturing.

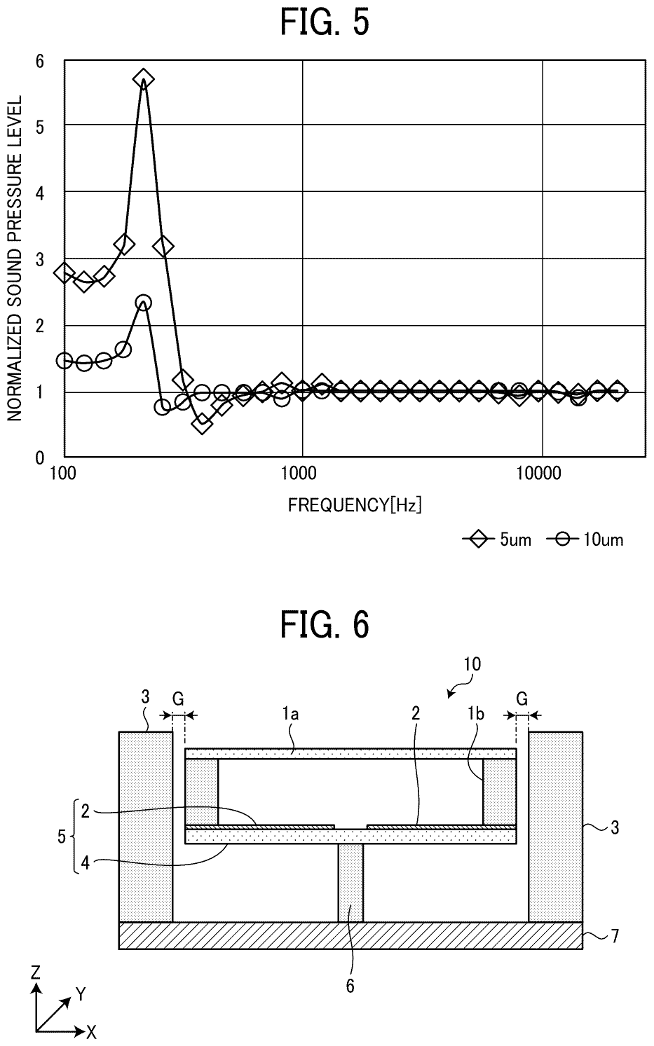

As illustrated in FIG. 5, a simulation of the sound pressure level was conducted for the embodiment example of the electroacoustic transducer illustrated in FIGS. 1 and 2, where the gap G was set to 5 μm and 10 μm. As illustrated in FIG. 5, the vertical axis represents the normalized sound pressure level, and the horizontal axis represents the frequency. As illustrated in FIG. 5, in the range from 100 Hz to 1000 Hz, setting the gap G to 5 μm resulted in an improved sound pressure level compared to setting the gap G to 10 μm.

In these embodiment examples as described above, the frame 3 is formed of the first frame 31 and the second frame 32, separately, but this is not limited to this configuration. FIG. 6 is a cross-sectional view of a further embodiment example of the electroacoustic transducer. In the further embodiment example as illustrated in FIG. 6, the first frame 31 and the second frame 32 of the frame 3 are formed integrally. Forming the first frame 31 and the second frame 32 integrally allows to prevent the reverse-phase sound waves generated on the back of the diaphragm 1a from wrapping around to the front side of the diaphragm 1a. Additionally, the driver supporter 6 and base 7 may also be formed integrally.

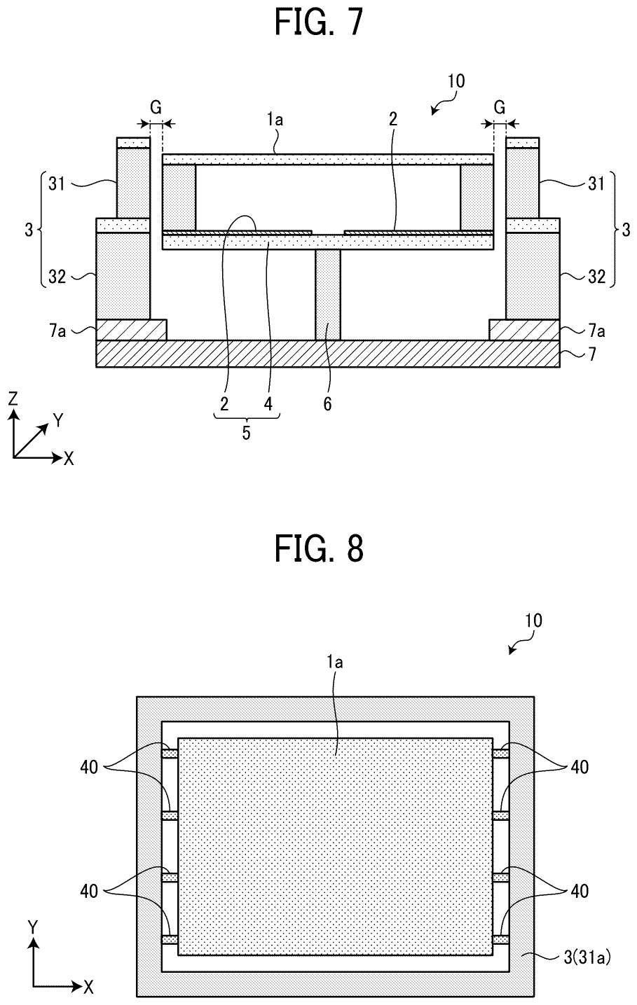

FIG. 7 is a cross-sectional view of a further embodiment example of the electroacoustic transducer. The further embodiment example as illustrated in FIG. 7 differs from the embodiment example as illustrated in FIGS. 1 and 2 in that the position where the base 7 supports the frame 3 is higher than the position where the base 7 supports driver supporter 6. In the following description of this embodiment example, descriptions similar to those of the embodiment example as illustrated in FIGS. 1 and 2 are omitted.

In the embodiment example as illustrated in FIG. 7, the base 7 has different heights (thicknesses in the direction of vibration of the diaphragm 1a) for the part supporting the frame 3 and the part supporting the driver support 6. Specifically, the base 7 includes a base 7a at the position supporting the frame 3, which makes the position supporting the frame 3 thicker than the position supporting the driver supporter 6. This thickness difference allows appropriate stress to the beam 40, making it easily breakable.

The base 7, including base 7a, is thicker at the position supporting the frame 3 than at the position supporting the driver support 6. In other words, when the thickness of the frame 3 is greater than the thickness (height) from the connection position of the driver support 6 and the base 7 to the diaphragm 1a, the frame 3 protrudes more than the surface of the diaphragm 1a when the driver 5 is not being driven.

The structure which the frame 3 protrudes more than the surface of the diaphragm 1a when the driver 5 is not being driven allows appropriate stress to the beam 40, making it easily breakable. This stress is generated by mechanical strain due to the height difference. This method allows for the efficient and accurate destruction of the beam 40.

The connection structure between the driver 5 and the diaphragm 1a, which uses the base 7 with a partially different thickness, allows more precise and effective control of the beam 40 breakage in MEMS devices. This connection structure enhances the reliability and performance of MEMS devices, allowing for broader applications.

Also, in the embodiment example as illustrated in FIG. 7, the first frame 31 surrounds the area around the maximum displacement position of the diaphragm 1a, allowing for the prevention of a gap greater than 5 μm between the diaphragm 1a and the first frame 31.

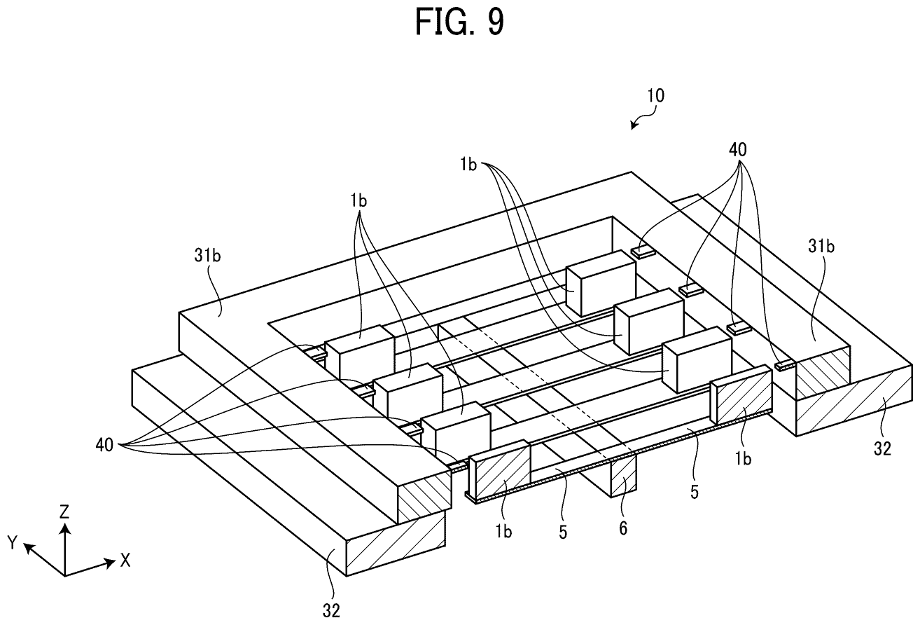

FIG. 8 is a plan view of a diaphragm and a frame of a further embodiment example of the electroacoustic transducer. FIG. 9 is a perspective view of a further embodiment example of the electroacoustic transducer, in which the illustration of a diaphragm and a base are omitted. The further embodiment example as illustrated in FIGS. 8 and 9 differs from the embodiment example as illustrated in FIGS. 1 and 2 in that the beam 40 is arranged near the position where the diaphragm supports 1b and the diaphragm 1a are connected. In the following description of this embodiment example, descriptions similar to those of the embodiment example as illustrated in FIGS. 1 and 2 are omitted.

In the further embodiment example as illustrated in FIGS. 8 and 9, the position of the beam 40 is arranged near the position where the diaphragm supports 1b and the diaphragm 1a are connected. The arrangement of the beam 40 so that the beam 40 is arranged near the connection position between the drive unit 5 and the diaphragm 1a, allows the beam 40 to break easily under specific operating conditions.

The position where the diaphragm supports 1b and the diaphragm 1a are connected is also the position where each of the diaphragm supports 1b is arranged on the driver 5.

The arrangement of the beam 40 so that the beam 40 is arranged near the position where each of the diaphragm supports 1b is arranged on the driver 5, allows the mechanical stress generated between the multiple diaphragm supporters 1b and the diaphragm 1a on the drive part 5 to be directly and efficiently transmitted to the beam 40.

For example, under specific pressure and temperature conditions, the interaction between the multiple diaphragm supports 1b on the driver 5 and the diaphragm 1a increases. As a result, the stress applied to the beam 40 increases. If the stress exceeds the design breaking threshold of the beam 40, the beam 40 will break, and the necessary functional changes and adjustments will be made.

The arrangement of the beams 40 in the further embodiment example as illustrated in FIGS. 8 and 9 allows for more direct and effective control of the beam 40 breakage in MEMS devices. The arrangement of the beams 40 also improves the responsiveness and reliability of the MEMS device, and allows for efficient and accurate control of the beam 40 breakage under specific operating conditions, enabling precise control of the device's behavior.

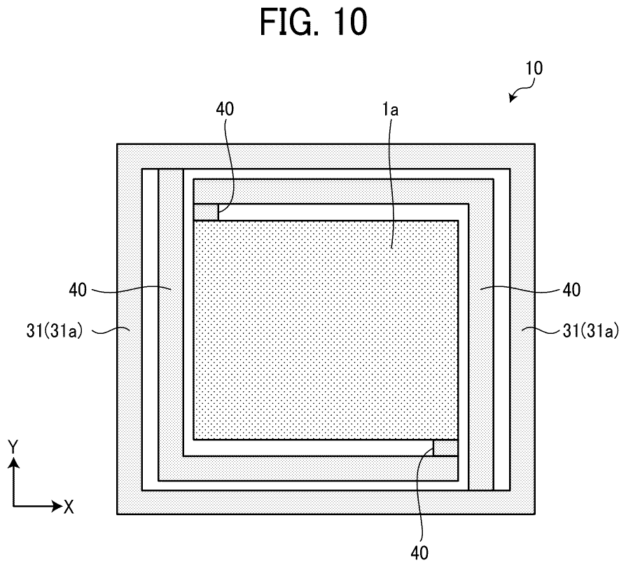

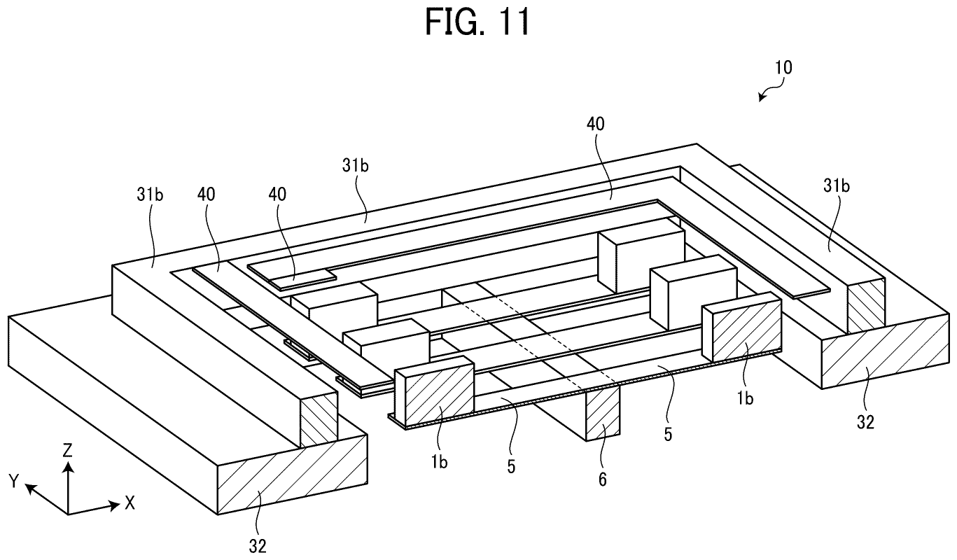

FIG. 10 is a plan view of a diaphragm and a frame of a further embodiment example of the electroacoustic transducer. FIG. 11 is a perspective view of a further embodiment example of the electroacoustic transducer, in which the illustration of a diaphragm and a base are omitted. The further embodiment example as illustrated in FIGS. 10 and 11 differs from the embodiment example as illustrated in FIGS. 1 and 2 in that the plurality of beams 40 are arranged so that destruction of the beams 40 can be controlled according to the amplitude of vibration (volume) generated by driving the electroacoustic transducer 10. In the following description of this embodiment example, descriptions similar to those of the embodiment example as illustrated in FIGS. 1 and 2 are omitted.

In the further embodiment example as illustrated in FIGS. 8 and 9, the electroacoustic transducer 10 includes at least two or more beams 40. The beams 40 are arranged to connect the first frame 31 and the diaphragm 1a. Specifically, the beams 40 are arranged to connect the diagonal line of the diaphragm 1a and to surround the outside of the diaphragm 1a. The total length of the beams 40 is equal to or longer than the outer circumference of the diaphragm 1a. The distance between the first frame 31 (first layer 31a) and the beam 40, the distance between the beam 40 and the diaphragm 1a, and the distance between the beams 40 may be 5 μm or less, respectively.

Arranging the beams 40 to connect the diagonal line of the diaphragm 1a and surround the outside of the diaphragm 1a allows to control the destruction according to the volume. Controlling the destruction according to the volume enables to achieve both durability when used at low volume and responsiveness when used at high volume. The material selection and cross-sectional shape of the beams 40 are optimized to achieve the desired displacement and destruction characteristics.

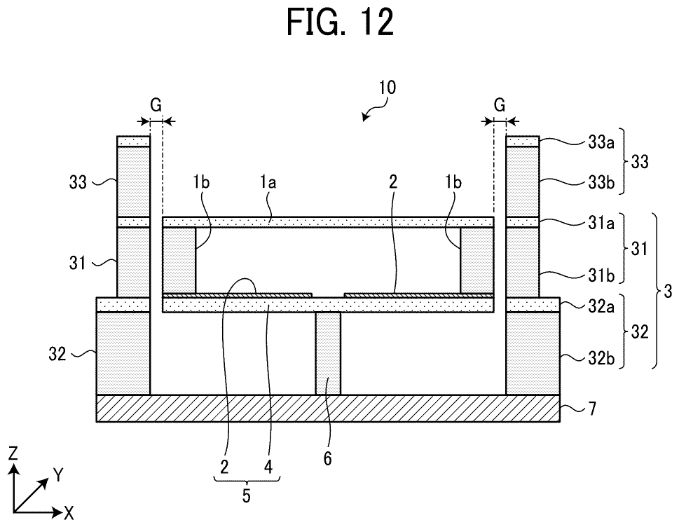

FIG. 12 is a cross-sectional view of a further embodiment example of the electroacoustic transducer. The further embodiment example as illustrated in FIG. 12 differs from the embodiment example as illustrated in FIGS. 1 and 2 in that the electroacoustic transducer 10 has a third frame 33. In the following description of this embodiment example, descriptions similar to those of the embodiment example as illustrated in FIGS. 1 and 2 are omitted.

In the further embodiment example as illustrated in FIG. 12, the frame 3 includes the third frame 33. The third frame 33 may be formed by the MEMS process. The third frame 33 is connected to the top of the first frame 31. The third frame 33 is disposed at higher position than the diaphragm 1a is disposed when the driver 5 is not being driven, in the vibration direction of the diaphragm 1a, so that the distance between the diaphragm 1a and the frame 3 is kept below 5 μm, even when the diaphragm 1a is at its maximum displacement.

In other words, the frame 3 protrudes more than the surface of the diaphragm 1a when the driver 5 is not being driven.

The structure which the frame 3 protrudes more than the surface of the diaphragm 1a when the driver 5 is not being driven allows to prevent sound waves from passing between the diaphragm 1a and the outer frame 3, and prevent a decrease in sound pressure level. In addition, forming the third frame 33 using the MEMS process enables the desired performance to be achieved without compromising product productivity. Therefore, the further embodiment example as illustrated in FIG. 12 improves the performance of MEMS speakers while also achieving more efficient manufacturing.

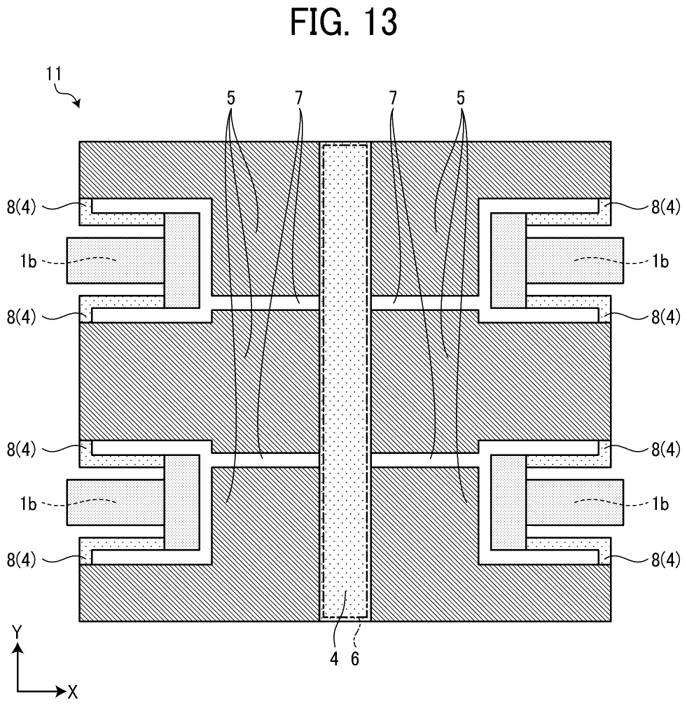

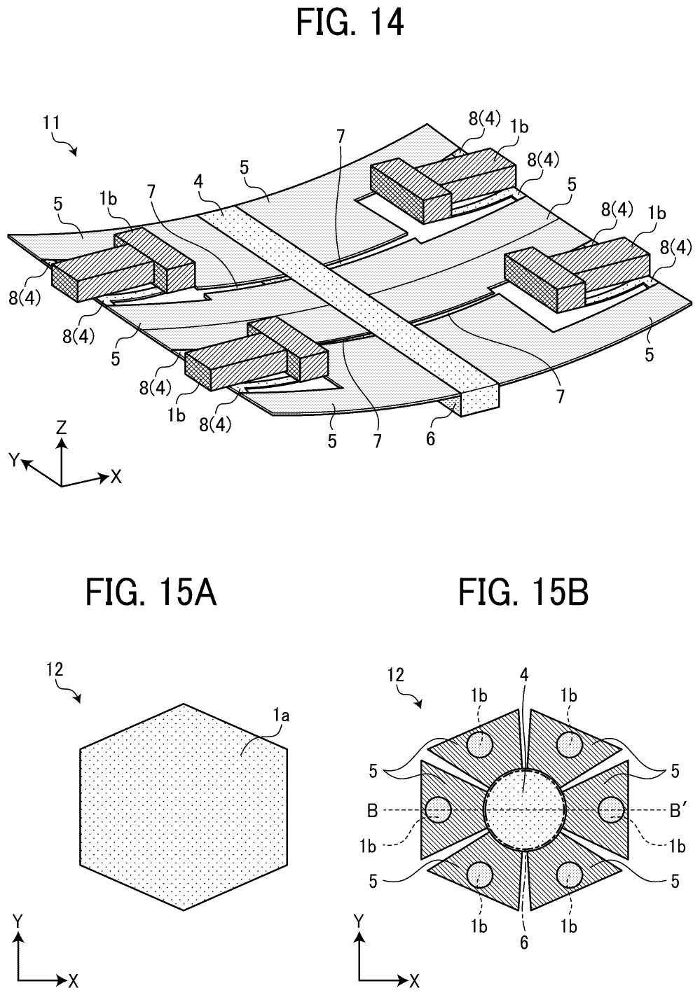

FIG. 13 is a plan view of a further embodiment example of the electroacoustic transducer, in which the illustration of a diaphragm, a frame and a base are omitted. FIG. 14 is a perspective view of the electroacoustic transducer illustrated in FIG. 13, in which the illustration of a diaphragm, a frame and a base are omitted. The further embodiment example as illustrated in FIGS. 13 and 14 differs from the embodiment example as illustrated in FIGS. 1 and 2 in that the driving plate 4 includes a spring 8 that displaces in the Z direction with respect to the driver 5. In the following description of this embodiment example, descriptions similar to those of the embodiment example as illustrated in FIGS. 1 and 2 are omitted.

In the further embodiment example as illustrated in FIGS. 13 and 14, The diaphragm supports 1b are arranged on the free end side (extended direction end side) between each pair of drivers 5 that are adjacent to each other in the Y direction, i.e. between adjacent drivers 5. The diaphragm support 1b are connected to the adjacent driver 5 via a pair of spring 8.

The spring 8 has a symmetrical shape relative to the connection position of the diaphragm 1a with the diaphragm support 1b. The spring 8 is formed by a portion of the driving plate 4 and has a folded structure extending from the free end of the driver 5 toward the fixed end. The folded structure of the spring 8 allows deformation in the Z direction relative to the driver 5, with the connection position of the spring 8 and the driver 5 as the rotation axis.

The diaphragm support 1b has a structure that allows it to be displaced in the direction of vibration of the diaphragm 1a relative to the driver 5 between adjacent drivers 5. The structure of the diaphragm supports 1b transmits only the component of the driving force of the driver 5 in the direction of vibration to the diaphragm 1a, and can increase the amplitude of vibration of the diaphragm 1a. Therefore, the structure of the diaphragm supports 1b allows to improve the sound pressure level per unit area of the diaphragm 1a. In addition, compared to when the spring section 8 is not provided, the diaphragm 1a allows to vibrate parallel to the Z-direction (vibration direction) with reduced distortion due to the driving force. Therefore, the distortion that occurs when the electroacoustic transducer 11 is driven can be further reduced. In addition, the width in the direction perpendicular to the direction of extension of each driver 5 (the short direction of the driver 5) differs between the edge side of the diaphragm 1a and the driver support 6. The width in the short direction at the end of the extension direction of the driver 5 is smaller than that on the side of the driver support 6. The difference in the width in the short direction of the driver 5 allows to suppress the increase in the area of arrangement due to the provision of the spring 8.

In the further embodiment example as illustrated in FIGS. 13 and 14, the electroacoustic transducer 11 includes three or more pairs of drivers 5 and two or more pairs of diaphragm supporters 1b which includes springs 8. In this embodiment example, the ratio of the length of the X direction to the Y direction of the driver 5 may be increased. Increasing the ratio of the length of the X direction to the Y direction of the driver 5 allows the ratio of the deformation of the X direction to the deformation of the Y direction of the driver 5 to become larger, and allows more efficient improvement of the sound pressure level (also referred to as the amplitude of the vibration generated) and reduction of total harmonic distortion (THD). In addition, since the diaphragm 1a can be supported at more points, the vibration of the diaphragm 1a can be further stabilized.

FIG. 15A is a plan view of a diaphragm of a further embodiment example of the electroacoustic transducer. FIG. 15B is a plan view of the electroacoustic transducer illustrated in FIG. 15A, in which the illustration of a diaphragm, a frame and a base are omitted. The further embodiment example as illustrated in FIGS. 15A and 15B differs from the embodiment example as illustrated in FIGS. 1 and 2 in that the diaphragm 1a is hexagonal. In the following description of this embodiment example, descriptions similar to those of the embodiment example as illustrated in FIGS. 1 and 2 are omitted.

The electroacoustic transducer 12 as illustrated in FIGS. 15A and 15B has six drivers 5 that extend radially from the driver support 6. The arrangement of six drivers 5 has point symmetry with respect to the drive support 6. The arrangement of the drivers 5 having point symmetry allows to cancel out vibration components generated in each driver 5 other than in the Z direction when the driver 5 being driven. In addition, the arrangement of the drivers 5 allows the diaphragm 1a to be further stabilized, which in turn reduces THD. The drivers 5 may not be limited to six, and three or more is sufficient.

In the direction of extension of each driver 5, the width of the edge side (edge side of diaphragm 1a) of each driver 5 in the short direction may be greater than or equal to the width of diaphragm supports 1b. This shape of each driver 5 allows the contact surface between the driver 5 and the diaphragm supports 1b to be more solid and prevents damage to unintended positions due to vibration, etc. caused by the drivers 5. The width of the driver support 6 side of the driver 5 in the short direction may be less than the width of the diaphragm supports 1b. This shape of each driver 5 allows to increase the number of drivers 5 that can be placed and allows the diaphragm 1a to be further stabilized.

As illustrated in FIG. 15B, each of the drivers 5 having point symmetry may have different widths in the transverse direction between the end of the driver 5 in the extending direction and the driver support 6. For example, the width in the transverse direction at the end of the driver 5 in the extending direction is larger than the width in the transverse direction near the driver support 6. Accordingly, the area of the driving sources 2 can be increased, and the driving force of the driver 5 can be increased. Such a configuration can enhance the drive sensitivity of the diaphragm 1.

The electroacoustic transducer 12 may be arranged in multiple locations on the same plane to form an array-type electroacoustic transducer (array speaker). Arranging multiple electroacoustic transducer 12 on the same plane allows to improve the directivity of the vibrations generated. In other words, it is possible to increase the distance over which the vibrations generated in the direction of vibration of the diaphragm 1a reach. The multiple electroacoustic transducer 12 may be arranged to form a close-packed arrangement, such as a triangular lattice to improve the directivity of the vibrations.

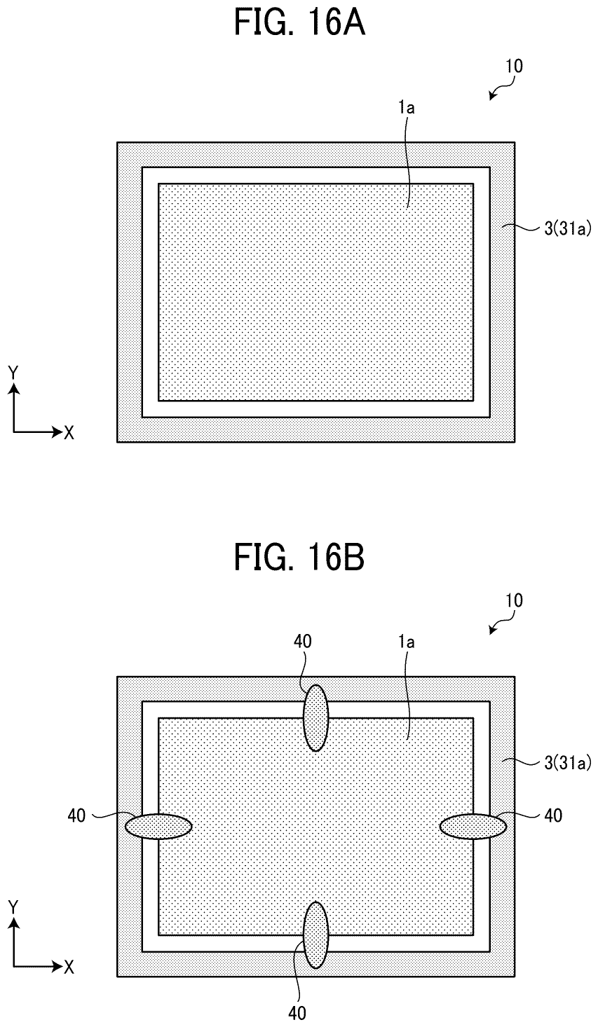

FIG. 16A is a plan view of a diaphragm and a frame of a further embodiment example of the electroacoustic transducer. FIG. 16B is a plan view of a diaphragm and a frame of the electroacoustic transducer illustrated in FIG. 16A. The further embodiment example as illustrated in FIGS. 16A and 16B differs from the embodiment examples as described above in that the beam 40 is formed using 3D printing technology. In the following description of this embodiment example, descriptions similar to those of the embodiment examples as described above are omitted.

In this the further embodiment example as illustrated in FIGS. 16A and 16B, a method for forming a beam 40 that is easily broken using 3D printing technology independently of the MEMS process be described. This embodiment example allows to improve the flexibility and efficiency of the manufacturing process of MEMS devices.

As illustrated in FIGS. 16A and 16B, the beam 40 that connects the diaphragm 1a and the frame 3 is formed independently of the MEMS process. Adopting 3D printing technology allows to change the design, shape and size of the beam 40 easily.

After the beam 40 have been formed using 3D printing technology, die bonding is performed to connect the diaphragm 1a, which is connected to the first frame 31 by the beam 40, to the driver 5 and the second frame 32 using an adhesive such as silver paste.

After the diaphragm 1a is connected to the driver 5, the beam 40 formed by 3D printing technology is removed or broken by, for example, dissolution or laser. This chemical removal process affects selectively on the beam 40, effectively removing or destroying only the beam 40 without damaging other MEMS structures.

Forming of the beam 40 using 3D printing technology improves the flexibility of the MEMS process and facilitates the integration of different materials and structures. In addition, forming of the beam 40 using 3D printing technology allows to form of complex beam structures that were difficult to achieve using conventional MEMS manufacturing methods, and improves the design and performance of MEMS devices.

As described above, forming of the beam 40 using 3D printing technology allows to improve flexibility and efficiency in the manufacturing process of MEMS devices.

The embodiment examples as described above can be applied not only to the electroacoustic transducer but also to an acoustic device including the electroacoustic transducer, such as an earphone, a headphone, or a speaker. Further, for example, such an acoustic device can be incorporated into a wearable device. The wearable device, such as a wristwatch, eyeglasses, a head-mounted display (HMD), or a body-mounted device, can be directly or indirectly mounted on the human body of a user.

In particular, an acoustic device to be incorporated in a wearable device preferably has a small size and low power consumption from the viewpoint of, for example, a long operation time, reduction in size and weight, and design. The embodiment examples as described above can enhance the sound pressure level per arrangement area of the electroacoustic transducer and per unit area of the diaphragm. In other words, according to embodiment examples as described above, an acoustic device can output a large sound with predetermined power while reducing the size of the electroacoustic transducer. Accordingly, the acoustic device to which the embodiment examples as described above is applied can prevent the entire wearable device from being increased in size and enhance the flexibility in design. At the same time, the acoustic device to which embodiment examples as described above is applied can reduce power consumption when outputting a sound. Applied cases will be described below.

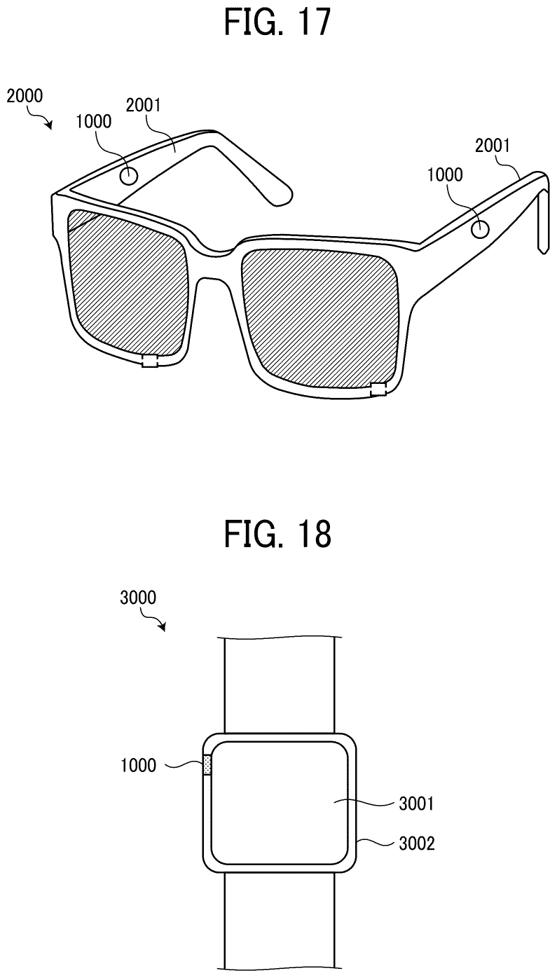

The details of an eyeglasses-type wearable device which the electroacoustic transducer as described above is applied will be described. below with reference to FIG. 17. In the following description of the embodiment example, descriptions of elements, which have already been described, identical or similar to those in embodiment examples as described above are omitted, and differences from embodiment examples as described above are described.

FIG. 17 is a schematic view of an eyeglasses-type wearable device according to the embodiment example of the present disclosure. An eyeglasses-type wearable device 2000 illustrated in FIG. 17 includes speaker 1000 and temples 2001 (i.e., a frame). The speaker 1000 corresponds to the electroacoustic transducer described in embodiment examples as described above. When the speaker 1000 is mounted on the eyeglasses-type wearable device 2000, the speaker 1000 is preferably disposed on the inner face of the temple 2001 (i.e., the surface facing the user when the user wears the wearable device). In particular, when the speaker 1000 is used as a bone conduction speaker, the speaker 1000 is preferably disposed at a position, where the surface of the head of the user is in contact with, on the temple 2001.

The details of a watch-type wearable device which the electroacoustic transducer as described above is applied will be described. below with reference to FIG. 18. In the following description of the embodiment example, descriptions of elements, which have already been described, identical or similar to those in embodiment examples as described above are omitted, and differences from embodiment examples as described above are described.

FIG. 18 is a schematic view of a watch-type wearable device according to the embodiment example of the present disclosure. A watch-type wearable device 3000 illustrated in FIG. 18 includes a speaker 1000, a liquid crystal display 3001, and an outer frame 3002 (i.e., a frame) of the liquid crystal display 3001. When the speaker 1000 is mounted on the watch-type wearable device 3000, the speaker 1000 is preferably disposed on the outer frame 3002 of the liquid crystal display 3001.

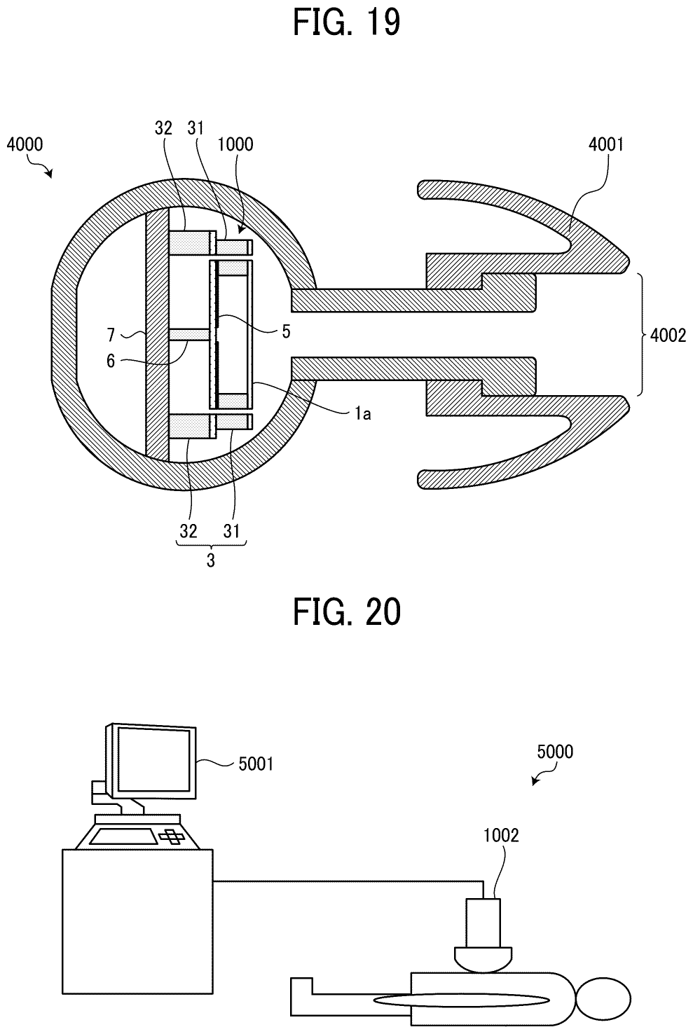

The details of an earphone speaker which the electroacoustic transducer as described above is applied will be described. below with reference to FIG. 19. In the following description of the embodiment example, descriptions of elements, which have already been described, identical or similar to those in embodiment examples as described above are omitted, and differences from embodiment examples as described above are described.

FIG. 19 is a schematic view of an earphone speaker according to the embodiment example of the present disclosure. An earphone speaker 4000 illustrated in FIG. 19 includes a speaker 1000, an attachment portion 4001 (e.g., ear pad, cap, plug, or piece) to be worn over (or inserted into) the ear of the user, and an opening 4002. When the speaker 1000 is mounted on the earphone speaker 4000, the opening 4002 of the attachment portion 4001 to be worn over the ear is preferably disposed on the normal line to the driving plate (or the diaphragm) of the speaker 1000.

Further, the electroacoustic transducers according to embodiment examples as described above can also be applied to, for example, an ultrasonic transmitter that generates ultrasonic waves by the vibration of the electroacoustic transducer.

The details of an ultrasonic transmitter which the electroacoustic transducer as described above is applied will be described. below with reference to FIG. 20. In the following description of the embodiment example, descriptions of elements, which have already been described, identical or similar to those in embodiment examples as described above are omitted, and differences from embodiment examples as described above are described.

FIG. 20 is a schematic view of an ultrasonic transmitter according to the embodiment example of the present disclosure. An ultrasonic transmitter 5000 illustrated in FIG. 20 includes at least an ultrasonic vibrator 1002 and a processing unit 5001. The ultrasonic vibrator 1002 corresponds to the electroacoustic transducer described in embodiment examples as described above. The ultrasonic transmitter 5000 outputs ultrasonic waves from the ultrasonic vibrator 1002 based on electrical signals controlled by the processing unit 5001.

Although the electroacoustic transducer according to an embodiment example of the present disclosure has been described above, the present disclosure is not limited to the above-described embodiment examples. Within a range conceivable by those skilled in the art, another embodiment example may be added, or elements may be added, changed, or omitted. Any one of such aspects that provides an action and an effect of the present disclosure is within the scope of the present disclosure.

Aspects of the present disclosure are, for example, as follows.

### Aspect 1

An electroacoustic transducer includes a diaphragm, a diaphragm support connected to a part of the diaphragm in a direction of vibration of the diaphragm, a driver connected to the diaphragm support and configured to vibrate the diaphragm, a driver support connected to the driver opposite to the diaphragm and configured to support a part of the driver, a base connected to the driver support and having a larger area than the diaphragm, a frame connected to the base from a same side as the driver support and disposed with a gap between an outside of the diaphragm and an outside of the driver.

### Aspect 2

In the electroacoustic transducer according to Aspect 1, a position where the driver and the diaphragm support are connected is disposed on an edge side of the driver compared to a position where the driver and the driver support are connected.

### Aspect 3

In the electroacoustic transducer according to Aspect 1 or 2, the diaphragm support includes a plurality of diaphragm supports.

### Aspect 4

In the electroacoustic transducer according to any one of Aspect 1 to 3, in a plane of the diaphragm which connects to the diaphragm support, the diaphragm support is disposed to be line-symmetrical with respect to a line passing through a center of gravity of the diaphragm.

### Aspect 5

In the electroacoustic transducer according to any one of Aspect 1 to 4, the driver includes a driving plate, and the frame includes a first frame which surrounds an outer circumference of the diaphragm and a second frame which surrounds an outer circumference of the driver, and the first frame includes a first layer of a same material as the diaphragm, and a second layer of a same material as the diaphragm support, and the second frame includes a third layer of a same material as the driver support, and a fourth layer of a same material as the driving plate.

### Aspect 6

In the electroacoustic transducer according to any one of Aspect 1 to 5, a distance between a connection position of the diaphragm support and the driver and a center of gravity of the driver is longer than a distance between a connection position of the driver support and the center of gravity of the driver.

### Aspect 7

In the electroacoustic transducer according to Aspect 5, a beam to connect the diaphragm and the first layer.

### Aspect 8

In the electroacoustic transducer according to Aspect 7, a width of the beam at a point where the beam connects to the diaphragm is less than ⅓ a length or diameter of the diaphragm.

### Aspect 9

In the electroacoustic transducer according to Aspect 7, the beam includes a narrow width region which reduces an area of the beam.

### Aspect 10

In the electroacoustic transducer according to Aspect 7, the beam is arranged substantially at a position where the diaphragm support and the diaphragm are connected.

### Aspect 11

In the electroacoustic transducer according to Aspect 7, the beam includes at least two or more beams,
at least two of the beams are arranged to surround the outer circumference of the diaphragm, and a total length of at least two of the beams is at least as long as the outer circumference of the diaphragm.

### Aspect 12

In the electroacoustic transducer according to Aspect 7, the frame protrudes more than a surface of the diaphragm when the driver is not being driven.

### Aspect 13

An array speaker includes multiple electroacoustic transducers including the electroacoustic transducer according to any one of Aspect 1 to 12.

### Aspect 14

A wearable device includes according to any one of Aspect 1 to 12 and a frame configured to mount the electroacoustic transducer.

### Aspect 15

A speaker includes the electroacoustic transducer according to any one of Aspect 1 to 12 and an opening disposed on a normal line to the diaphragm to output a sound from the electroacoustic transducer.

### Aspect 16

An ultrasonic transmitter includes the electroacoustic transducer according to any one of Aspect 1 to 12 wherein the electroacoustic transducer outputs ultrasonic waves.

### Aspect 17

A method of manufacturing electroacoustic transducer includes a first step forming a first structure including a diaphragm, a diaphragm support, a first frame, and a beam, wherein the diaphragm support is connected to a part of the diaphragm in a direction of vibration of the diaphragm, and the first frame surrounds an outer circumference of the diaphragm and second frame surrounds an outer circumference of the driver, and the beam connects the diaphragm and the first layer, a second step forming a second structure which includes a driver, a driver support, and a second frame, wherein the driver vibrates the diaphragm, and the driver support supports a part of the driver, and a base connected to the driver support and having a larger area than the diaphragm, and the second frame which surrounds the outer circumference of the driver, a third step connecting the first structure and the second structure, a fourth step removing or breaking the beam, wherein the first frame is disposed with a gap between the outer circumference of the diaphragm and the outer circumference of the driver.

### Aspect 18

In method of manufacturing electroacoustic transducer according to Aspect 17, a fifth step connecting the second structure with a base after the second or third step, wherein the base has a larger area than the diaphragm.

### Aspect 19

In method of manufacturing electroacoustic transducer according to Aspect 18, at a position of the base supporting the frame is thicker than the position of the base supporting the driver support.

1. An electroacoustic transducer comprising:
a diaphragm;
a diaphragm support connected to a part of the diaphragm in a direction of vibration of the diaphragm;
a driver connected to the diaphragm support and configured to vibrate the diaphragm;
a driver support connected to the driver opposite to the diaphragm and configured to support a part of the driver;
a base connected to the driver support and having a larger area than the diaphragm;
a frame connected to the base from a same side as the driver support and disposed with a gap between an outside of the diaphragm and an outside of the driver.

2. The electroacoustic transducer according to claim 1, wherein:
a position where the driver and the diaphragm support are connected is disposed on an edge side of the driver compared to a position where the driver and the driver support are connected.

3. The electroacoustic transducer according to claim 1, wherein:
the diaphragm support includes a plurality of diaphragm supports.

4. The electroacoustic transducer according to claim 1, wherein:
in a plane of the diaphragm which connects to the diaphragm support, the diaphragm support is disposed to be line-symmetrical with respect to a line passing through a center of gravity of the diaphragm.

5. The electroacoustic transducer according to claim 1, wherein:
the driver includes a driving plate, and
the frame includes a first frame which surrounds an outer circumference of the diaphragm and a second frame which surrounds an outer circumference of the driver, and
the first frame includes a first layer of a same material as the diaphragm, and a second layer of a same material as the diaphragm support, and
the second frame includes a third layer of a same material as the driver support, and a fourth layer of a same material as the driving plate.

6. The electroacoustic transducer according to claim 1, wherein:
a distance between a connection position of the diaphragm support and the driver and a center of gravity of the driver is longer than a distance between a connection position of the driver support and the center of gravity of the driver.

7. The electroacoustic transducer according to claim 5, further comprising:
a beam to connect the diaphragm and the first layer.

8. The electroacoustic transducer according to claim 7, wherein:
a width of the beam at a point where the beam connects to the diaphragm is less than ⅓ a length or diameter of the diaphragm.

9. The electroacoustic transducer according to claim 7, wherein:
the beam includes a narrow width region which reduces an area of the beam.

10. The electroacoustic transducer according to claim 7, wherein:
the beam is arranged substantially at a position where the diaphragm support and the diaphragm are connected.

11. The electroacoustic transducer according to claim 7, wherein:
the beam includes at least two or more beams,
at least two of the beams are arranged to surround the outer circumference of the diaphragm, and
a total length of at least two of the beams is at least as long as the outer circumference of the diaphragm.

12. The electroacoustic transducer according to claim 7, wherein:
the frame protrudes more than a surface of the diaphragm when the driver is not being driven.

13. An array speaker comprising multiple electroacoustic transducers including the electroacoustic transducer according to claim 1.

14. A wearable device comprising:
the electroacoustic transducer according to claim 1; and
a frame configured to mount the electroacoustic transducer.

15. A speaker comprising:
the electroacoustic transducer according to claim 1; and
an opening disposed on a normal line to the diaphragm to output a sound from the electroacoustic transducer.

16. An ultrasonic transmitter comprising the electroacoustic transducer according to claim 1, wherein:
the electroacoustic transducer outputs ultrasonic waves.

17. A method of manufacturing electroacoustic transducer comprising:
a first step forming a first structure including a diaphragm, a diaphragm support, a first frame, and a beam, wherein:
the diaphragm support is connected to a part of the diaphragm in a direction of vibration of the diaphragm; and
the first frame surrounds an outer circumference of the diaphragm and second frame surrounds an outer circumference of the driver; and
the beam connects the diaphragm and the first layer,
a second step forming a second structure which includes a driver, a driver support, and a second frame, wherein:
the driver vibrates the diaphragm; and
the driver support supports a part of the driver; and
a base connected to the driver support and having a larger area than the diaphragm; and
the second frame which surrounds the outer circumference of the driver,
a third step connecting the first structure and the second structure,
a fourth step removing or breaking the beam, wherein:
the first frame is disposed with a gap between the outer circumference of the diaphragm and the outer circumference of the driver.

18. The method of manufacturing electroacoustic transducer according to claim 17, further comprising:
a fifth step connecting the second structure with a base after the second or third step, wherein:
the base has a larger area than the diaphragm.

19. The method of manufacturing electroacoustic transducer according to claim 18, wherein:
at a position of the base supporting the frame is thicker than the position of the base supporting the driver support.
